(19) United States
(12) Patent Application Publication
(10) Pub. No.: US 2026/0198076 A1
(43) Pub. Date: Jul. 9, 2026

(54) SEMICONDUCTOR DEVICE

(71) Applicant: Samsung Electronics Co., Ltd., Suwon-si (KR)

(72) Inventors: Myungjin CHUNG, Suwon-si (KR); Keonil KIM, Suwon-si (KR); Jinkyu KIM, Suwon-si (KR); Inhyun SONG, Suwon-si (KR); Ghil-Geun OH, Suwon-si (KR); Eunguk CHUNG, Suwon-si (KR); Keun Hwi CHO, Suwon-si (KR)

(21) Appl. No.: 19/283,744

(22) Filed: Jul. 29, 2025

(30) Foreign Application Priority Data
Jan. 6, 2025 (KR) 10-2025-0001726

(51) Int. Cl. H10D 84/83; H01L 23/528; H10D 30/00; H10D 30/01; H10D 30/43; H10D 62/10; H10D 62/13; H10D 64/23; H10D 84/01

(52) U.S. Cl. CPC H10D 84/832; H10D 30/43; H10D 30/502; H10D 62/121; H10D 62/151; H10D 64/256; H10D 84/8312; H10W 20/43; H10W 20/435; H10D 30/014; H10D 30/019; H10D 84/0149

(57) ABSTRACT

A semiconductor device includes a substrate including an active region extending in a first direction, a sheet pattern disposed on the active region, a first gate electrode surrounding the sheet pattern and extending in a second direction, a first source/drain pattern disposed on a first side of the sheet pattern, a second source/drain pattern disposed on a second side of the sheet pattern opposite the first side, a power wiring on a lower surface of the substrate, wherein the power wiring extends in the first direction, and includes a first portion having a first width in the second direction and a second portion having a second width in the second direction that is less than the first width, and a lower wiring disposed below the power wiring, wherein the lower wiring does not overlap with the second portion of the power wiring in a third direction perpendicular to the lower surface of the substrate.

### CROSS-REFERENCE TO RELATED APPLICATION

This application claims priority to Korean Patent Application No. 10-2025-0001726, filed in the Korean Intellectual Property Office on Jan. 6, 2025, the entire contents of which are hereby incorporated by reference.

### BACKGROUND

### Field

The present disclosure relates to a semiconductor device.

### Description of Related Art

A semiconductor device (e.g., a semiconductor chip) is a core component used in an electronic device to control or amplify an electrical signal, and various types of semiconductor devices can be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

With the development of industry, the performance and function requirements of the electronic devices are also increasing. Accordingly, high-performance characteristics in semiconductor devices are essentially required, and the integration density of the semiconductor devices is increasing to meet these requirements. Various methods for forming semiconductor devices having excellent performance and improved integration density are being studied.

### SUMMARY

In order to solve one or more problems (e.g., the problems described above and/or other problems not explicitly described herein), the present disclosure provides a semiconductor device with improved reliability.

In order to solve one or more problems (e.g., the problems described above and/or other problems not explicitly described herein), the present disclosure provides a method for manufacturing a semiconductor device with improved reliability.

According to some embodiments of the present disclosure, a semiconductor device may include a substrate including an active region extending in a first direction, a sheet pattern disposed on the active region, a first gate electrode surrounding the sheet pattern and extending in a second direction that intersects with the first direction, a first source/drain pattern on the active region, wherein the first source/drain pattern is disposed on a first side of the sheet pattern, a second source/drain pattern on the active region, wherein the second source/drain pattern is disposed on a second side of the sheet pattern opposite the first side, a power wiring on a lower surface of the substrate, wherein the power wiring extends in the first direction, and includes a first portion having a first width in the second direction and a second portion having a second width in the second direction that is less than the first width, and a lower wiring disposed below the power wiring, wherein the lower wiring does not overlap with the second portion of the power wiring in a third direction that is perpendicular to the lower surface of the substrate.

According to some embodiments of the present disclosure, a semiconductor device may include a substrate including an active region extending in a first direction, a sheet pattern disposed on the active region, a first gate electrode surrounding the sheet pattern and extending in a second direction that intersects with the first direction, a first source/drain pattern on the active region, wherein the first source/drain pattern is disposed on a first side of the sheet pattern, a second source/drain pattern on the active region, wherein the second source/drain pattern is disposed on a second side of the sheet pattern, a power wiring disposed on a lower surface of the substrate, extending in the first direction, and overlapping with the active region in a third direction that is perpendicular to the lower surface of the substrate, a lower wiring insulating layer disposed on a lower surface of the power wiring, and an insulating layer disposed between the lower surface of the substrate and the lower wiring insulating layer and overlapping with at least a portion of the power wiring in the first direction.

According to some embodiments of the present disclosure, a semiconductor device may include a substrate including an active region extending in a first direction, a sheet pattern disposed on the active region, a first gate electrode surrounding the sheet pattern and extending in a second direction that intersects with the first direction, a first source/drain pattern on the active region, wherein the first source/drain pattern is disposed on a first side of the sheet pattern, a second source/drain pattern on the active region, wherein the second source/drain pattern is disposed on a second side of the sheet pattern, a power wiring on a lower surface of the substrate, wherein the power wiring extends in the first direction, and includes a first portion having a first width in the second direction and a second portion having a second width in the second direction that is less than the first width, an upper source/drain contact disposed on the second source/drain pattern, a lower source/drain contact disposed on an upper surface of the power wiring and penetrating through a lower surface of the first source/drain pattern, and a lower wiring disposed below the power wiring, wherein the lower wiring does not overlap with the second portion of the power wiring in a third direction that is perpendicular to the lower surface of the substrate, the active region overlaps with the power wiring in the third direction, and the second portion overlaps with the upper source/drain contact in the third direction.

According to some embodiments of the present disclosure, a method for manufacturing a semiconductor device is provided, which may include forming a source/drain pattern, a sheet pattern, and a gate electrode on a substrate, and forming a power wiring and an insulating layer extending on a lower surface of the substrate in the first direction, in which the power wiring may include a first portion having a first width in a second direction that intersects with the first direction and a second portion having a second width less than the first width in the second direction, and the insulating layer may be disposed on the second portion.

According to some embodiments of the present disclosure, the second portion may include a concave first side surface.

According to some embodiments of the present disclosure, the second portion may further include a concave second side surface opposite to the concave first side surface.

According to some embodiments of the present disclosure, the power wiring may include a through hole, and the insulating layer may be disposed within the through hole.

According to some embodiments of the present disclosure, the insulating layer may overlap with the source/drain pattern in a direction perpendicular to the lower surface of the substrate.

According to some embodiments of the present disclosure, the insulating layer may overlap with the gate electrode in a direction perpendicular to the lower surface of the substrate.

According to some embodiments of the present disclosure, the method for manufacturing the semiconductor device may further include forming, below the power wiring, the lower wiring insulating film including the keep-out region and the lower wiring disposed within the lower wiring insulating film, in which the lower wiring may not be disposed on the keep-out region.

According to some embodiments of the present disclosure, the method for manufacturing the semiconductor device may further include forming the lower wiring and the dummy wiring below the power wiring and removing the dummy wiring structure.

According to some embodiments of the present disclosure, the insulating layer is disposed on the side surface of the power wiring and the insulating layer, the keep-out region, and the upper source/drain contact overlap in a vertical direction, thereby allowing for the inspection of the electrical characteristics of the semiconductor device that includes the upper source/drain contact. Accordingly, the reliability of the semiconductor device can be improved.

### BRIEF DESCRIPTION OF THE DRAWINGS

The above and other embodiments and features of the present disclosure will become more apparent by describing in detail example embodiments thereof with reference to the attached drawings, in which:

FIG. 1 is a plan view of a semiconductor device according to some embodiments;

FIG. 2 is a plan view of a semiconductor device according to some embodiments;

FIG. 3 is a cross-sectional view taken along line A-A of FIG. 2;

FIG. 4 is a cross-sectional view taken along line B-B of FIG. 2;

FIG. 5 is a diagram of a semiconductor device according to some embodiments;

FIG. 6 is a diagram of a semiconductor device according to some embodiments;

FIG. 7 is a diagram of a semiconductor device according to some embodiments;

FIGS. 8 and 9 are diagrams of a semiconductor device according to some embodiments;

FIGS. 10 and 11 are diagrams of a semiconductor device according to some embodiments;

FIGS. 12 and 13 are diagrams of a semiconductor device according to some embodiments;

FIG. 14 is a diagram of a semiconductor device according to some embodiments;

FIGS. 15 and 16 are diagrams of a semiconductor device according to some embodiments;

FIG. 17 is a diagram of a semiconductor device according to some embodiments;

FIGS. 18 to 20 are diagrams of a semiconductor device according to some embodiments;

FIG. 21 is a diagram of a semiconductor device according to some embodiments;

FIG. 22 is a diagram of a semiconductor device according to some embodiments;

FIG. 23 is a diagram of a semiconductor device according to some embodiments;

FIGS. 24 to 30 are diagrams illustrating intermediate stages in a method for manufacturing a semiconductor device according to some embodiments.

### DETAILED DESCRIPTION

Hereinafter, a semiconductor device and a method for manufacturing the same according to some embodiments of the present disclosure will be described in detail with reference to the drawings. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Hereinafter, example embodiments will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes. Components described as “actively electrically connected” refers to components that are electrically connected through at least one active element that is in an “on” state to allow electrical signals to pass therethrough.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

As used herein, the term “dummy” is used to refer to a component that has the same or similar structure and shape as other components and may provide similar physical characteristics but does not function substantially the same as the same or similar structure (e.g., does not convey information or electrical signals). In some instances, a “dummy” element may be electrically floated, or may be connected to various voltage sources but otherwise not provide the same functionality of the non-dummy element it represents. For example, a dummy wiring may not form a complete electrical path between elements.

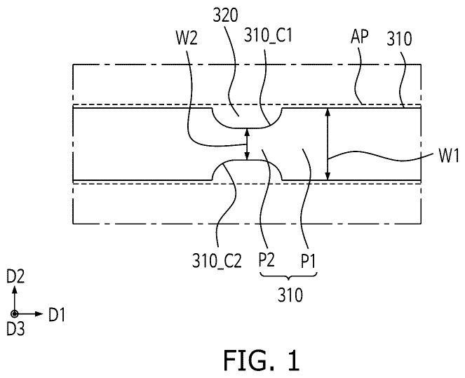

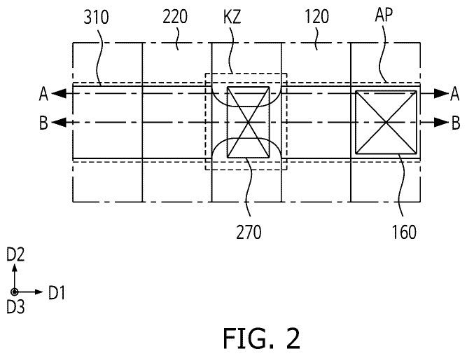

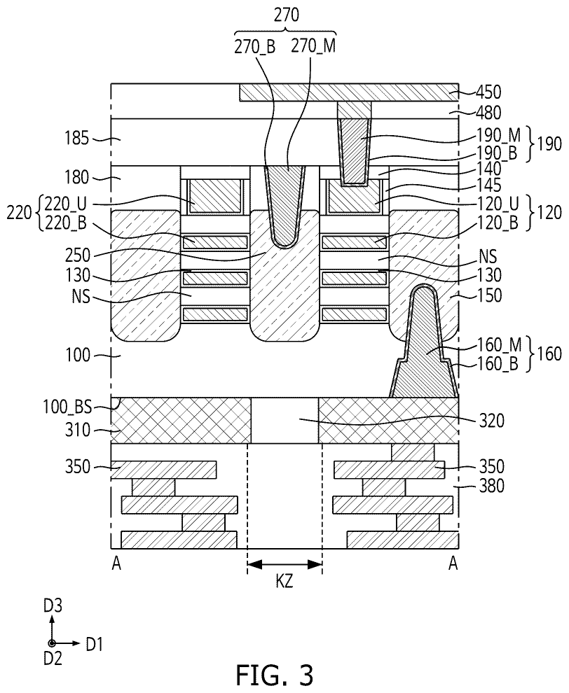

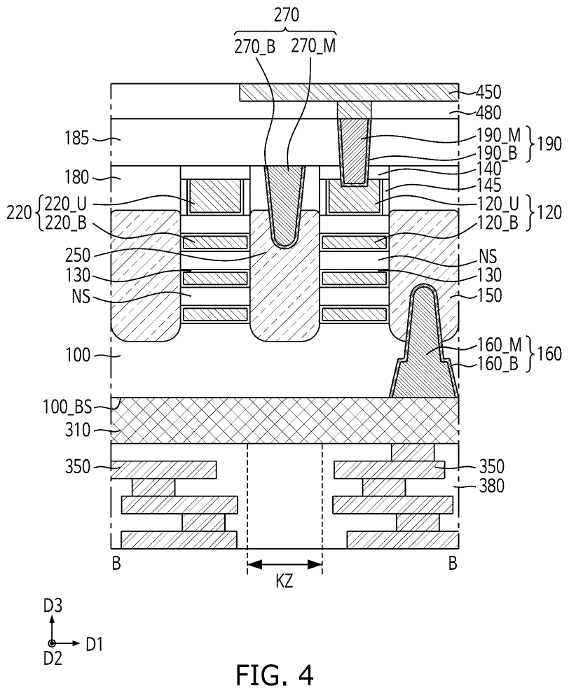

FIG. 1 is a plan view of a semiconductor device according to some embodiments. FIG. 2 is a plan view provided to explain a semiconductor device according to some embodiments. FIG. 3 is a cross-sectional view taken along line A-A of FIG. 2. FIG. 4 is a cross-sectional view taken along line B-B of FIG. 2. For reference, in FIG. 1, an illustration of features other than an active region AP, a power wiring 310, and an insulating layer 320 may be omitted for clarity and a description thereof may be omitted as well. The power wiring 310 may be a buried power rail that provides electrical power to transistors in the semiconductor device. For example, the power wiring may provide a substantially constant voltage (although the voltage may vary in magnitude depending on a power requirement of the semiconductor device) during the operation of the semiconductor device, as opposed to a signal wiring in which the voltage varies according to a signal. The power wiring 310 may distribute an externally supplied voltage to the transistors or may distribute an internally regulated voltage to the transistors.

Referring to FIGS. 1 to 4, the semiconductor device according to some embodiments may include a substrate 100, a plurality of sheet patterns NS, a first gate electrode 120, a second gate electrode 220, a gate insulating layer 130, a first source/drain pattern 150, a second source/drain pattern 250, a lower source/drain contact 160, an upper source/drain contact 270, a first interlayer insulating layer 180, a second interlayer insulating layer 185, a gate capping pattern 140, a gate spacer 145, a gate contact 190, the power wiring (e.g., a power rail) 310, the insulating layer 320, a lower wiring 350, and an upper wiring 450. The lower wiring 350 may be a combination of layers of horizontal conductive patterns and vertical conductive patterns connecting portions of the horizontal conductive patterns. Similarly, the upper wiring 350 may be a combination of layers of horizontal conductive patterns and vertical conductive patterns connecting portions of the horizontal conductive patterns.

The substrate 100 may be an insulating substrate. For example, during manufacturing, an initial semiconductor substrate may be removed and replaced with an insulating substrate. For example, the substrate 100 may include at least one of silicon oxide, silicon nitride, silicon oxynitride, and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination of these. However, embodiments are not limited to the above.

The substrate 100 may include the active region AP. The active region AP may be a region where the plurality of sheet patterns NS, the first source/drain pattern 150, and the second source/drain pattern 250, which will be described below, are disposed. The active region AP may extend in a first direction D1. The first direction D1 may intersect with a second direction D2. For example, the first direction D1 may be perpendicular to the second direction D2. A third direction D3 may intersect with each of the first and second directions D1 and D2. For example, the third direction D3 may be perpendicular to each of the first and second directions D1 and D2. The first and second directions D1 and D2 may be parallel to a lower surface 100_BS of the substrate 100, and the third direction D3 may be perpendicular to the lower surface 100_BS of the substrate 100.

The plurality of sheet patterns NS may be disposed on the active region AP. The plurality of sheet patterns NS may be spaced apart from the substrate 100 in the third direction D3. Each of the plurality of sheet patterns NS may be spaced apart from each other in the third direction D3. In some embodiments, the sheet pattern NS may have a nanosheet shape. Although it is illustrated that there are three sheet patterns NS, embodiments are not limited thereto.

The sheet patterns NS may include one of an elemental semiconductor material such as silicon (Si), silicon germanium (SiGe), a group IV-IV compound semiconductor, or a group III-V compound semiconductor.

For example, the group IV-IV compound semiconductor may be a binary compound or a ternary compound including at least two or more of carbon (C), silicon (Si), germanium (Ge), and tin (Sn).

For example, the group III-V compound semiconductor may be one of a binary compound, a ternary compound, or a quaternary compound formed by a combination of at least one of aluminum (Al) or gallium (Ga), and indium (In) as a group III element and one of phosphorus (P), arsenic (As), and antimony (Sb) as a group V element.

The first gate electrode 120 may disposed on the substrate 100 and extend in the second direction D2. The first gate electrode 120 may intersect with the active region AP. The first gate electrode 120 may surround a plurality of sheet patterns NS. The first gate electrode 120 may surround four surfaces of the sheet pattern NS. For example, the first gate electrode 120 may surround an upper surface, a lower surface, and opposing side surfaces of the sheet pattern NS. The upper and lower surfaces of the sheet pattern NS may refer to surfaces that are opposite to each other in the third direction D3, and the side surfaces of the sheet pattern NS may refer to surfaces that are opposite to each other in the second direction D2.

The first gate electrode 120 may include a first upper gate electrode 120_U and a first lower gate electrode 120_B. The first lower gate electrode 120_B may be disposed between sheet patterns NS adjacent to each other in the third direction D3 and between the substrate 100 and the sheet pattern NS disposed at the bottom among the plurality of sheet patterns NS. The first upper gate electrode 120_U may be disposed on an upper surface of the sheet pattern NS disposed at the top among the plurality of sheet patterns NS. In some embodiments, a height of the first upper gate electrode 120_U in the third direction D3 may be greater than a height of the first lower gate electrode 120_B in the third direction D3. However, embodiments are not limited to the above.

In some embodiments, the number of first lower gate electrodes 120_B may be proportional to the number of sheet patterns NS. For example, the number of the first lower gate electrodes 120_B may be the same as the number of the sheet patterns NS. As illustrated in FIG. 3, the number of the first lower gate electrodes 120_B is three, which may be the same as the number of sheet patterns NS.

The second gate electrode 220 may disposed on the substrate 100 and extend in the second direction D2. The second gate electrode 220 may intersect with the active region AP. The second gate electrode 220 may surround a plurality of sheet patterns NS. The second gate electrode 220 may be spaced apart from the first gate electrode 120 in the first direction D1. The second source/drain pattern 250 may be disposed between the first gate electrode 120 and the second gate electrode 220.

The second gate electrode 220 may include a second upper gate electrode 220_U and a second lower gate electrode 220_B. Descriptions of the second upper gate electrode 220_U and the second lower gate electrode 220_B may be the same as those of the first upper gate electrode 120_U and the first lower gate electrode 120_B.

Each of the first gate electrode 120 and the second gate electrode 220 may include at least one of a metal, a metal alloy, a conductive metal nitride, a metal silicide, a doped semiconductor material, a conductive metal oxide, or a conductive metal oxynitride. For example, each of the first gate electrode 120 and the second gate electrode 220 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination of these, but embodiments are not limited thereto. The conductive metal oxide and the conductive metal oxynitride may include an oxidized form of the material described above, but is not limited thereto.

The gate insulating layer 130 may be disposed between the gate electrodes 120 and 220 and the plurality of sheet patterns NS, between the gate electrodes 120 and 220 and the substrate 100, and between the gate electrodes 120 and 220 and source/drain patterns 150 and 250. For convenience of description, the first gate electrode 120 will be primarily described below. The gate insulating layer 130 may be disposed between the first upper gate electrode 120_U and the sheet pattern NS disposed at the top among the plurality of sheet patterns NS. The gate insulating layer 130 may be disposed between the first lower gate electrode 120_B and the sheet pattern NS. The first gate electrode 120 and the plurality of sheet patterns NS may be spaced apart from each other, and the first gate electrode 120 and the source/drain patterns 150 and 250 may be spaced apart from each other by the gate insulating layer 130.

In some embodiments, the gate insulating layer 130 may include a plurality of films. For example, the gate insulating layer 130 may include an interfacial insulating layer and a high-k insulating layer. For example, the interfacial insulating layer may include silicon oxide. The high-k insulating layer may include a high-k material having a dielectric constant greater than that of the interfacial insulating layer. For example, the high-k insulating layer may include at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The first source/drain pattern 150 may be disposed on the substrate 100. The first source/drain pattern 150 may be disposed on the active region AP. The first source/drain pattern 150 may be connected to the sheet pattern NS. A portion of a side surface of the first source/drain pattern 150 may be in contact with the sheet pattern NS. Another portion of the side surface of the first source/drain pattern 150 may be in contact with the gate insulating layer 130. The first source/drain pattern 150 may be disposed on one side of the first gate electrode 120.

The first source/drain pattern 150 may be an epitaxial pattern formed by a selective epitaxial growth process using the sheet pattern NS as a seed. The first source/drain pattern 150 may serve as a source/drain of a transistor that uses the sheet pattern NS as a channel region.

The lower source/drain contact 160 may be disposed on an upper surface of the power wiring 310. A portion of the lower source/drain contact 160 may be surrounded by the substrate 100. The lower source/drain contact 160 may be formed to penetrate through a lower surface of the first source/drain pattern 150. One end of the lower source/drain contact 160 may be disposed within the first source/drain pattern 150. The lower source/drain contact 160 may connect the first source/drain pattern 150 and the power wiring 310. For example, the first source/drain pattern 150 and the power wiring 310 may be electrically connected by the lower source/drain contact 160.

In some embodiments, a side surface of the lower source/drain contact 160 may include a step. An inclination of the side surface of the lower source/drain contact 160 may not be constant.

The lower source/drain contact 160 may include a barrier film 160_B and a conductive filling film 160_M disposed within the barrier film 160_B. The conductive filling film 160_M may fill a space within the barrier film 160_B. The barrier film 160_B may be in contact with the first source/drain pattern 150, and the conductive filling film 160_M may be in contact with the upper surface of the power wiring 310.

For example, the barrier film 160_B of the lower source/drain contact 160 may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a two-dimensional material (2D material). The conductive filling film 160_M of the lower source/drain contact 160 may include at least one of aluminum (Al), copper (Cu), tungsten (W), cobalt (Co), ruthenium (Ru), silver (Ag), gold (Au), manganese (Mn), or molybdenum (Mo).

The second source/drain pattern 250 may be disposed on the substrate 100. The second source/drain pattern 250 may be disposed on the active region AP. The second source/drain pattern 250 may be connected to the sheet pattern NS. A portion of a side surface of the second source/drain pattern 250 may be in contact with the sheet pattern NS. Another portion of the side surface of the second source/drain pattern 250 may be in contact with the gate insulating layer 130. The second source/drain pattern 250 may be disposed between the first gate electrode 120 and the second gate electrode 220.

The first source/drain pattern 150 may be spaced apart from the second source/drain pattern 250 in the first direction D1. The sheet pattern NS and the first gate electrode 120 may be disposed between the first source/drain pattern 150 and the second source/drain pattern 250. The first source/drain pattern 150 may be connected to the second source/drain pattern 250 through the sheet pattern NS.

Each of the first source/drain pattern 150 and the second source/drain pattern 250 may include a semiconductor material. Each of the first source/drain pattern 150 and the second source/drain pattern 250 may include, for example, an element semiconductor material such as silicon (Si) or germanium (Ge). In addition, for example, the first source and drain pattern 150 may include a binary compound or a ternary compound including at least two or more of carbon (C), silicon (Si), germanium (Ge), or tin (Sn), or these compounds doped with a group IV element. For example, the first source/drain pattern 150 may include silicon (Si), silicon-germanium (SiGe), germanium (Ge), silicon carbide (SiC), etc., but is not limited thereto.

Each of the first source/drain pattern 150 and the second source/drain pattern 250 may include an impurity doped into a semiconductor material. The doped impurities may include at least one of boron (B), phosphorus (P), carbon (C), arsenic (As), antimony (Sb), bismuth (Bi), or oxygen (O), but embodiments are not limited thereto.

Although each of the first source/drain pattern 150 and the second source/drain pattern 250 is illustrated as a single film, this is only for convenience of description and embodiments are not limited thereto. Each of the first source/drain pattern 150 and the second source/drain pattern 250 may include a plurality of films including different materials. In another aspect, each of the first source/drain pattern 150 and the second source/drain pattern 250 may include the same material, and may include a plurality of layers having different concentrations of constituent materials.

The first interlayer insulating layer 180 may be disposed on an upper surface of the first source/drain pattern 150 and an upper surface of the second source/drain pattern 250. The first interlayer insulating layer 180 may be disposed on a side surface of the gate spacer 145 and a side surface of the gate capping pattern 140. In some embodiments, an upper surface of the first interlayer insulating layer 180 may be disposed on the same plane as an upper surface of the gate capping pattern 140. However, embodiments are not limited to the above.

In some embodiments, unlike the illustration, an etching stop film may be disposed on the upper surface of the first source/drain pattern 150 and the upper surface of the second source/drain pattern 250. The etching stop film may be disposed between the upper surface of the first source/drain pattern 150 and the first interlayer insulating layer 180, and between the upper surface of the second source/drain pattern 250 and the second interlayer insulating layer 185. For example, the etching stop film may include at least one of silicon nitride (SiN), silicon oxide (SiO), silicon oxynitride (SiON), silicon carbonate nitride (SiOCN), silicon boron nitride (SiBN), silicon oxide boron nitride (SiOBN), silicon oxynitride (SiOC), or a combination of these.

The upper source/drain contact 270 may be disposed on the second source/drain pattern 250. The upper source/drain contact 270 may be formed to penetrate through the first interlayer insulating layer 180 and the upper surface of the second source/drain pattern 250. For example, one end of the upper source/drain contact 270 may be disposed within the second source/drain pattern 250. The upper source/drain contact 270 may be connected to the second source/drain pattern 250.

The upper source/drain contact 270 may include a barrier film 270_B and a conductive filling film 270_M disposed within the barrier film 270_B. Descriptions of the materials of the barrier film 270_B and the conductive filling film 270_M of the upper source/drain contact 270 may be the same as the descriptions of the barrier film 160_B and the conductive filling film 160_M of the lower source/drain contact 160.

The gate spacer 145 may be disposed on the side surfaces of the upper gate electrodes 120_U and 220_U. For example, the gate spacer 145 may extend along the side surface of the first upper gate electrode 120_U. The gate spacer 145 may not be positioned between the sheet patterns NS adjacent to each other in the third direction D3.

For example, the gate spacer 145 may include at least one of silicon nitride (SiN), silicon nitride oxide (SiON), silicon oxide (SiO2), silicon carbonate nitride (SiOCN), silicon boron nitride (SiBN), silicon oxide boron nitride (SiOBN), silicon oxide carbonate (SiOC), or a combination of these. Although it is illustrated that the gate spacer 145 is a single film, this is only for convenience of description, and embodiments are not limited thereto.

The gate capping pattern 140 may be disposed on an upper surface of the first upper gate electrode 120_U and an upper surface of the gate spacer 145. The gate capping pattern 140 may cover the upper surface of the first upper gate electrode 120_U. Although the gate capping pattern 140 is illustrated to be in contact with the upper surface of the gate spacer 145, embodiments are not limited thereto. For example, the gate capping pattern 140 may be disposed between the gate spacers 145 and may be in contact with one surface of the gate spacer 145.

For example, the gate capping pattern 140 may include at least one of silicon nitride (SiN), silicon oxynitride (SiON), silicon carbonitride (SiCN), silicon oxycarbonitride (SiOCN), or a combination of these. The gate capping pattern 140 may include a material having etch selectivity with respect to the first interlayer insulating layer 180.

The second interlayer insulating layer 185 may be disposed on the first interlayer insulating layer 180 and the gate capping pattern 140. The second interlayer insulating layer 185 may cover the upper surface of the first interlayer insulating layer 180 and the upper surface of the gate capping pattern 140.

Each of the first interlayer insulating layer 180 and the second interlayer insulating layer 185 may include at least one of, for example, silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination of these, but is not limited thereto.

The gate contact 190 may be formed to penetrate through the second interlayer insulating layer 185, the gate capping pattern 140, and an upper surface of the first gate electrode 120. For example, the gate contact 190 may be formed to penetrate through the upper surface of the first upper gate electrode 120_U. One end of the gate contact 190 may be disposed within the first upper gate electrode 120_U. The gate contact 190 may be connected to the first gate electrode 120.

The gate contact 190 may include a barrier film 190_B and a conductive filling film 190_M disposed within the barrier film 190_B. Descriptions of the materials of the barrier film 190_B and the conductive filling film 190_M of the gate contact 190 may be the same as the descriptions of the barrier film 160_B and the conductive filling film 160_M of the lower source/drain contact 160.

The upper wiring 450 may be disposed on the gate contact 190. The upper wiring 450 may be connected to the gate contact 190. The upper wiring 450 and the first gate electrode 120 may be electrically connected by the gate contact 190. An upper wiring insulating layer 480 may be disposed on the second interlayer insulating layer 185. The upper wiring 450 may be disposed within the upper wiring insulating layer 480.

The power wiring 310 may be disposed on the lower surface 100_BS of the substrate 100. The power wiring 310 may extend in the first direction D1. The active region AP may overlap with the power wiring 310 in the third direction D3. The power wiring 310 may include a first portion P1 having a first width W1 in the second direction D2 and a second portion P2 having a second width W2 in the second direction D2. The second width W2 may be less than the first width W1. In some embodiments, the length of the second width W2 may be 40% or less of the length of the first width W1. However, embodiments are not limited to the above.

In some embodiments, the power wiring 310 may include a first side surface 310_C1 and a second side surface 310_C2. The first side surface 310_C1 and the second side surface 310_C2 may be opposing side surfaces of the second portion P2. From a planar perspective, each of the first side surface 310_C1 and the second side surface 310_C2 of the second portion P2 may have a recessed shape. The first side surface 310_C1 and the second side surface 310_C2 may be opposite to each other in the second direction D2. The second width W2 of the second portion P2 may be less than the first width W1 of the first portion P1 due to the concave shapes of the first side surface 310_C1 and the second side surface 310_C2.

Each of the first portion P1 and the second portion P2 may overlap with the active region AP in the third direction D3. In some embodiments, a portion of the active region AP may not overlap with the power wiring 310 in the third direction D3. For example, the active region AP may include a first region overlapping with the power wiring 310 in the third direction D3 and a second region not overlapping with the power wiring 310 in the third direction D3. For example, as illustrated in FIG. 1, from a planar perspective, the power wiring 310 may expose a portion of the active region AP.

The insulating layer 320 may be disposed at the same level as the power wiring 310. The insulating layer 320 may be disposed on the lower surface 100_BS of the substrate 100. The insulating layer 320 may be disposed between the lower surface 100_BS of the substrate 100 and a lower wiring insulating layer 380. The insulating layer 320 may be disposed on a side surface of the power wiring 310. For example, the insulating layer 320 may be disposed on the side surfaces 310_C1 and 310_C2 of the second portion P2 of the power wiring 310. A portion of the insulating layer 320 may overlap with the power wiring 310 in the first direction D1.

The insulating layer 320 may include an insulating material. For example, the insulating layer 320 may include any one of silicon oxide (SiO), silicon nitride (SiN), silicon oxynitride (SiON), silicon carbide (SiC), silicon carbon nitride (SiCN), and silicon oxycarbonitride (SiOCN). However, embodiments are not limited to the above. For example, the material of the insulating layer 320 may be the same as the material of the first interlayer insulating layer 180. In some embodiments, an air gap may be further included within the insulating layer 320. It should be appreciated that an “air gap” may comprise a gap having air or other gases (e.g., such as those present during manufacturing) or may comprise a gap forming a vacuum therein. The term “air” as discussed herein, may refer to atmospheric air, or other gases that may be present during the manufacturing process. The air gap may be disposed within the insulating layer 320 or between the insulating layer 320 and the second portion P2 of the power wiring 310.

Referring again to FIGS. 1 to 4, at least a portion of the second source/drain pattern 250 may not overlap with the second portion P2 of the power wiring 310 in the third direction D3. For example, a portion of the second source/drain pattern 250 may overlap with the second portion P2 of the power wiring 310, and the remaining portion of the second source/drain pattern 250 may overlap with the insulating layer 320 in the third direction D3. At least a portion of the upper source/drain contact 270 may not overlap with the second portion P2 of the power wiring 310 in the third direction D3. For example, a portion of the upper source/drain contact 270 may overlap with the second portion P2 of the power wiring 310 in the third direction D3, and the remaining portion of the upper source/drain contact 270 may overlap with the insulating layer 320 in the third direction D3. For example, as illustrated in FIG. 3, a portion of the second source/drain pattern 250 may overlap with the insulating layer 320 in the third direction D3, and a portion of the upper source/drain contact 270 may overlap with the insulating layer 320 in the third direction D3.

In some embodiments, the width of the active region AP in the second direction D2 and the width (e.g., the first width W1) of the power wiring 310 in the second direction D2 may be the same as each other. However, embodiments are not limited to the above. For example, the width of the active region AP in the second direction D2 and the width of the power wiring 310 in the second direction D2 may be different from each other.

The lower wiring insulating layer 380 may be disposed on a lower surface of the power wiring 310. The lower wiring 350 may be disposed within the lower wiring insulating layer 380. The lower wiring 350 may be connected to the power wiring 310. The lower wiring 350 may not overlap with the second portion P2 of the power wiring 310 in the third direction D3.

In some embodiments, the lower wiring insulating layer 380 may include a keep-out region KZ. The lower wiring 350 may not be disposed on the keep-out region KZ. For example, only the lower wiring insulating layer 380 may be disposed on the keep-out region KZ. The keep-out region KZ may overlap with the second portion P2 and the insulating layer 320 of the power wiring 310 in the third direction D3. The keep-out region KZ may overlap with each of the second source/drain pattern 250 and the upper source/drain contact 270 in the third direction D3. For example, the lower wiring 350 may not be disposed below the second source/drain pattern 250 and the upper source/drain contact 270.

There is a need for a method for inspecting a defective transistor among the transistors included in the semiconductor device. In order to improve electrical characteristics and integration density of the semiconductor device, a power wiring and lower wiring may be formed on the back side of the substrate. Traditionally, a defect inspection, such as an optical defect inspection, may examine the backside of the chip to identify the location of a defect (e.g., the defect might have a thermal signature visible through the substrate). However, when wiring structures are in place in both the front side and backside of the semiconductor device, the wiring structures may obscure the defect. In this case, the method for inspecting a defect of the transistor through the back side of the substrate may be limited by the power wiring and the lower wiring structure.

In the semiconductor device according to some embodiments, the insulating layer 320 may be disposed on the side surfaces 310_C1 and 310_C2 of the second portion P2 of the power wiring 310. The shape of the side surfaces 310_C1 and 310_C2 of the second portion P2 may allow the insulating layer 320 and the upper source/drain contact 270 to overlap in the third direction D3. In addition, by forming the keep-out region KZ within the lower wiring insulating layer 380 where the lower wiring 350 is not disposed, the lower wiring 350 may not be disposed below the upper source/drain contact 270. Accordingly, the electrical characteristics of the transistor including the upper source/drain contact 270 may be inspected through the keep-out region KZ and the insulating layer 320. For example, the electrical characteristics of a transistor that uses the first gate electrode 120 as a gate electrode may be inspected. Accordingly, the reliability of the semiconductor device can be improved.

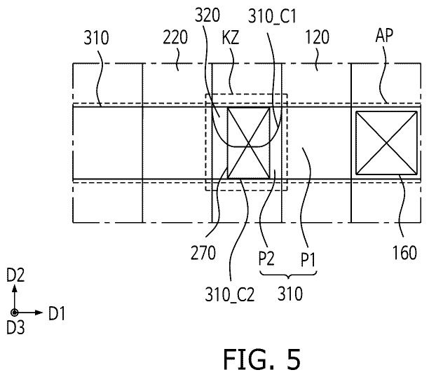

FIG. 5 is a diagram of a semiconductor device according to some embodiments. For convenience of description, features that are the same, substantially the same, or similar to those described previously may have their description omitted and different configurations from those described in FIGS. 1 to 4 will be primarily described.

Referring to FIG. 5, in the semiconductor device according to some embodiments, the insulating layer 320 may be disposed on the first side surface 310_C1 of the power wiring 310.

The power wiring 310 may include the first portion P1 and the second portion P2. The width of the second portion P2 in the second direction D2 may be less than the width of the first portion P1 in the second direction D2. The power wiring 310 may include the first side surface 310_C1 and the second side surface 310_C2 that is opposite to the first side surface 310_C1 in the second direction D2. The first side surface 310_C1 may be recessed, and the second side surface 310_C2 may extend parallel to the first direction D1. The insulating layer 320 may be disposed on the first side surface 310_C1 of the power wiring 310. The insulating layer 320 may overlap with the upper source/drain contact 270 in the third direction D3.

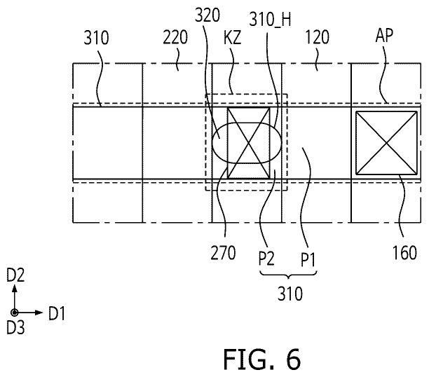

FIG. 6 is a diagram of a semiconductor device according to some embodiments. For convenience of description, features that are the same, substantially the same, or similar to those described previously may have their description omitted and different configurations from those described in FIGS. 1 to 4 will be primarily described.

Referring to FIG. 6, the semiconductor device according to some embodiments may further include a through hole 310_H disposed within the power wiring 310. The through hole 310_H may be disposed on the active region AP. The through hole 310_H may overlap with the active region AP in the third direction D3. For example, the through hole 310_H may overlap with each of a portion of the second source/drain pattern 250 of FIG. 3 and a portion of the upper source/drain contact 270 in the third direction D3.

In some embodiments, the insulating layer 320 may be disposed within the through hole 310_H. The insulating layer 320 may fill the through hole 310_H. However, embodiments are not limited to the above. For example, the interior of the through hole 310_H may be an empty space (e.g., filled with an ambient gas, other gas, or a partial vacuum). The through hole 310_H may be referred to as a cavity or an air gap.

The insulating layer 320 may overlap with each of a portion of the second source/drain pattern 250 of FIG. 3 and a portion of the upper source/drain contact 270 in the third direction D3. From a planar perspective, the insulating layer 320 may be disposed in the keep-out region KZ.

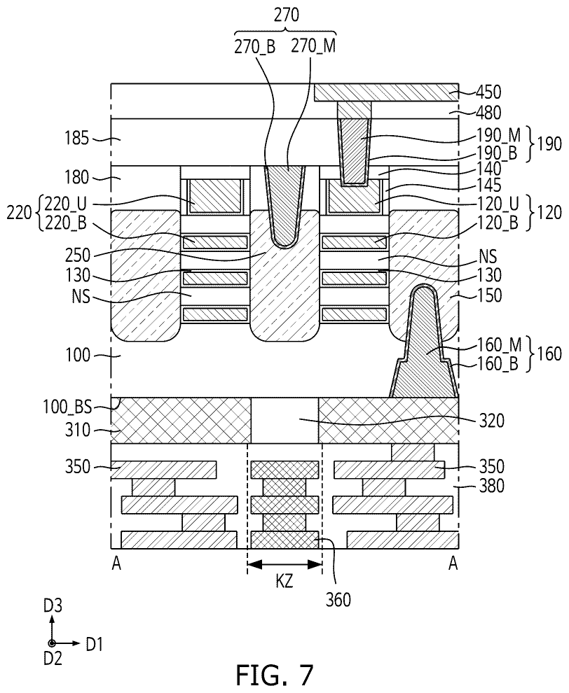

FIG. 7 is a diagram of a semiconductor device according to some embodiments. For reference, FIG. 7 may correspond to a cross-sectional view taken along line A-A of FIG. 2. For convenience of description, features that are the same, substantially the same, or similar to those described previously may have their description omitted and different configurations from those described in FIGS. 1 to 4 will be primarily described.

Referring to FIG. 7, the semiconductor device according to some embodiments may further include a dummy wiring 360.

The dummy wiring 360 may be disposed within the lower wiring insulating layer 380. From a planar perspective, the dummy wiring 360 may be disposed in the keep-out region KZ. For example, the dummy wiring 360 may overlap with the keep-out region KZ in the third direction D3. The dummy wiring 360 may be surrounded by the lower wiring insulating layer 380. For example, the dummy wiring 360 may be spaced apart from the lower wiring 350 in the first direction D1 by the lower wiring insulating layer 380. The dummy wiring 360 may be spaced apart from the power wiring 310 in the third direction D3 by the lower wiring insulating layer 380. The dummy wiring 360 may not be connected to the power wiring 310 and the lower wiring 350. Thus, the dummy wiring 360 differs from the lower wiring in that it is not used to supply power to the transistors of the semiconductor device.

In some embodiments, the dummy wiring 360 may be formed by the same process as the lower wiring 350. By forming the dummy wiring 360, relatively uniform stress may be applied to the lower wiring 350. As a result, the reliability of the semiconductor device may be improved.

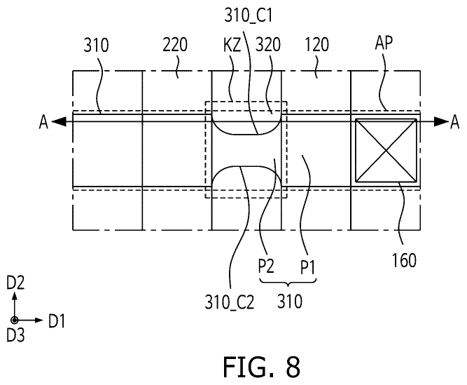

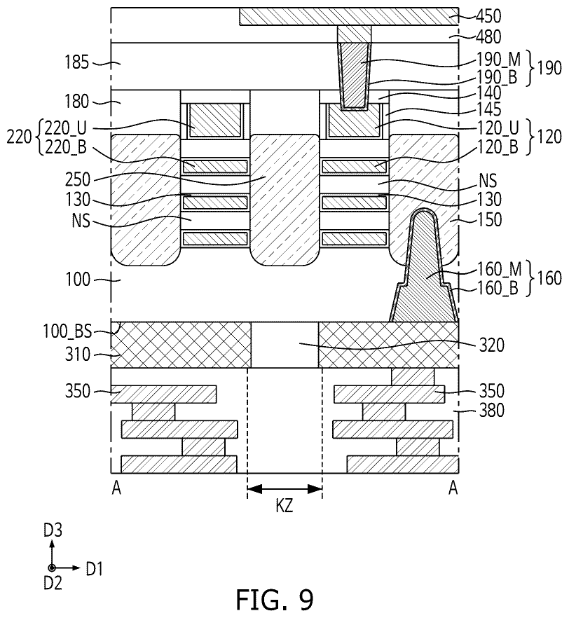

FIGS. 8 and 9 are diagrams of a semiconductor device according to some embodiments. For reference, FIG. 8 may be a plan view of the semiconductor device according to some embodiments, and FIG. 9 may be a cross-sectional view taken along line A-A of FIG. 8. For convenience of description, features that are the same, substantially the same, or similar to those described previously may have their description omitted and different configurations from those described in FIGS. 1 to 4 will be primarily described.

Referring to FIGS. 8 and 9, the semiconductor device according to some embodiments may not include the upper source/drain contact 270 described previously, unlike the embodiments described in FIGS. 1 to 4.

The second portion P2 of the power wiring 310 may overlap with the second source/drain pattern 250 in the third direction D3. The insulating layer 320 may overlap with the second source/drain pattern 250 in the third direction D3.

The insulating layer 320 may be disposed on the side surfaces 310_C1 and 310_C2 of the second portion P2 of the power wiring 310. The shape of the side surfaces 310_C1 and 310_C2 of the second portion P2 may allow the insulating layer 320 and the second source/drain pattern 250 to overlap in the third direction D3. Accordingly, the electrical characteristics of the transistor that includes the second source/drain pattern 250 may be inspected through the keep-out region KZ and the insulating layer 320. For example, the electrical characteristics of a transistor that uses the second source/drain pattern 250 as a source or drain may be inspected.

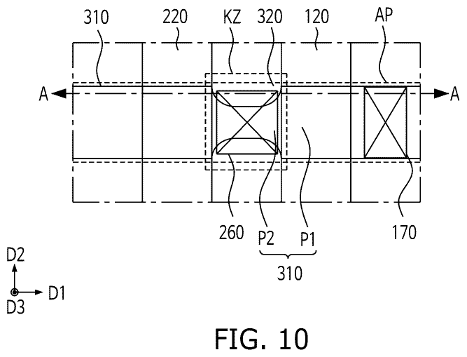

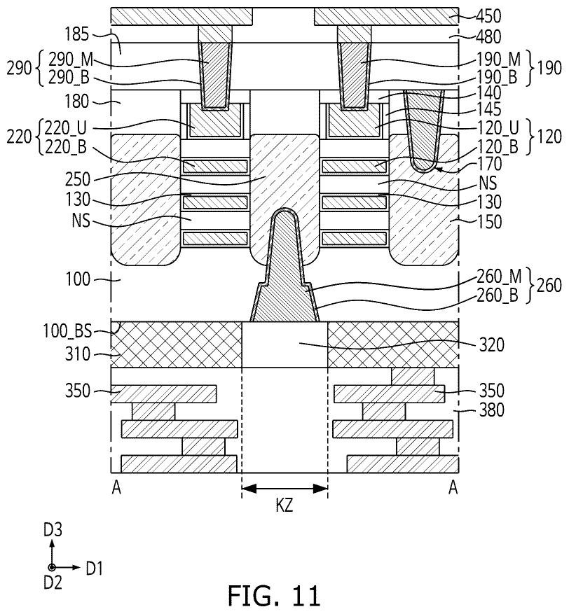

FIGS. 10 and 11 are diagrams of a semiconductor device according to some embodiments. For reference, FIG. 10 may be a plan view of a semiconductor device according to some embodiments, and FIG. 11 may be a cross-sectional view taken along line A-A of FIG. 10. For convenience of description, features that are the same, substantially the same, or similar to those described previously may have their description omitted and different configurations from those described in FIGS. 1 to 4 will be primarily described.

Referring to FIGS. 10 and 11, in the semiconductor device according to some embodiments, a portion of a lower source/drain contact 260 may be disposed on the insulating layer 320.

The lower source/drain contact 260 may be disposed on the second source/drain pattern 250. For example, the lower source/drain contact 260 may be disposed between the power wiring 310 and the second source/drain pattern 250. The power wiring 310 and the second source/drain pattern 250 may be connected by the lower source/drain contact 260. The lower source/drain contact 260 may be disposed on the keep-out region KZ. For example, from a planar perspective, the lower source/drain contact 260 may be disposed in the keep-out region KZ. The lower source/drain contact 260 may overlap with the keep-out region KZ in the third direction D3.

The lower source/drain contact 260 may be disposed on the second portion P2 of the power wiring 310 and the insulating layer 320. A portion of the lower source/drain contact 260 may not overlap with the second portion P2 of the power wiring 310 in the third direction D3. For example, a portion of the lower source/drain contact 260 may overlap with the second portion P2 of the power wiring 310 in the third direction D3, and the remaining portion of the lower source/drain contact 260 may overlap with the insulating layer 320 in the third direction D3. For example, from a planar perspective, the power wiring 310 may expose a portion of the lower source/drain contact 260.

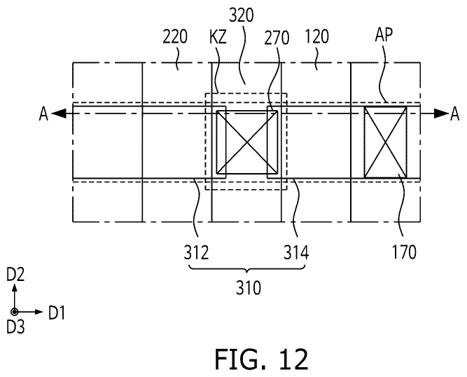

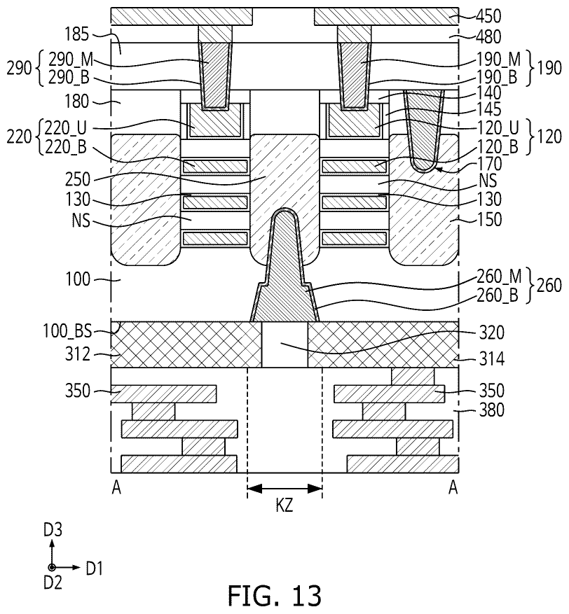

FIGS. 12 and 13 are diagrams of a semiconductor device according to some embodiments. For reference, FIG. 12 may be a plan view of the semiconductor device according to some embodiments, and FIG. 13 may be a cross-sectional view taken along line A-A of FIG. 12. For convenience of description, features that are the same, substantially the same, or similar to those described previously may have their description omitted and different configurations from those described in FIGS. 1 to 4 will be primarily described.

Referring to FIGS. 12 and 13, in the semiconductor device according to some embodiments, the power wiring 310 may include a first sub-power wiring 312 and a second sub-power wiring 314.

Each of the first sub-power wiring 312 and the second sub-power wiring 314 may extend in the first direction D1. The first sub-power wiring 312 may be spaced apart from the second sub-power wiring 314 in the first direction D1. The first sub-power wiring 312 and the second sub-power wiring 314 may overlap in the first direction D1. For example, the width of the first sub-power wiring 312 in the second direction D2 and the width of the second sub-power wiring 314 in the second direction D2 may be the same as each other.

The insulating layer 320 may be disposed between the first sub-power wiring 312 and the second sub-power wiring 314. The first sub-power wiring 312 and the second sub-power wiring 314 may be spaced apart from each other in the first direction D1 by the insulating layer 320.

The lower source/drain contact 260 may be disposed on the second source/drain pattern 250. For example, the lower source/drain contact 260 may be disposed between the power wiring 310 and the second source/drain pattern 250 and between the insulating layer 320 and the second source/drain pattern 250. The power wiring 310 and the second source/drain pattern 250 may be connected by the lower source/drain contact 260. Specifically, one end of the first sub-power wiring 312 may be connected to the lower source/drain contact 260, and one end of the second sub-power wiring 314 may be connected to the lower source/drain contact 260. The first sub-power wiring 312 may be connected to the second sub-power wiring 314 through the lower source/drain contact 260. The lower source/drain contact 260 may be disposed on the keep-out region KZ. For example, from a planar perspective, the lower source/drain contact 260 may be disposed in the keep-out region KZ.

A portion of the lower source/drain contact 260 may not overlap with the power wiring 310 in the third direction D3. For example, a portion of the lower source/drain contact 260 may overlap with the first sub-power wiring 312 in the third direction D3, another portion of the lower source/drain contact 260 may overlap with the second sub-power wiring 314 in the third direction D3, and the remaining portion of the lower source/drain contact 260 may overlap with the insulating layer 320 in the third direction D3. For example, from a planar perspective, the power wiring 310 may expose a portion of the lower source/drain contact 260.

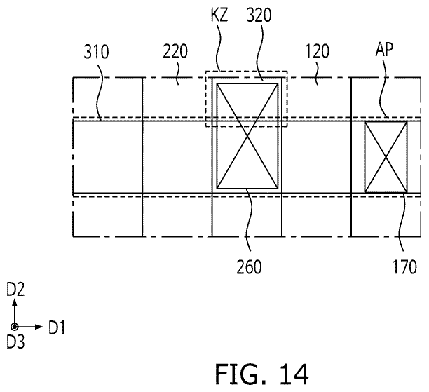

FIG. 14 is a diagram of a semiconductor device according to some embodiments. For convenience of description, features that are the same, substantially the same, or similar to those described previously may have their description omitted and different configurations from those described in FIGS. 1 to 4 will be primarily described.

Referring to FIG. 14, in the semiconductor device according to some embodiments, the width of the lower source/drain contact 260 in the second direction D2 may be different from the width of the power wiring 310 in the second direction D2.

The lower source/drain contact 260 may be disposed between the second source/drain pattern 250 of FIG. 3 and the power wiring 310. The width of the lower source/drain contact 260 in the second direction D2 may be greater than the width of the power wiring 310 in the second direction D2. In some embodiments, a portion of the lower source/drain contact 260 may not overlap with the power wiring 310 in the third direction D3. For example, from a planar perspective, the power wiring 310 may expose a portion of the lower source/drain contact 260. For example, one end of the lower source/drain contact 260 may protrude from the power wiring 310 in the second direction D2.

The width of the lower source/drain contact 260 in the second direction D2 may be greater than the width of the active region AP in the second direction D2. In some embodiments, a portion of the lower source/drain contact 260 may not overlap with the active region AP in the third direction D3. For example, one end of the lower source/drain contact 260 may protrude from the active region AP in the second direction D2. The keep-out region KZ may be disposed in a region of the lower source/drain contact 260 that does not overlap with the power wiring 310 in the third direction D3.

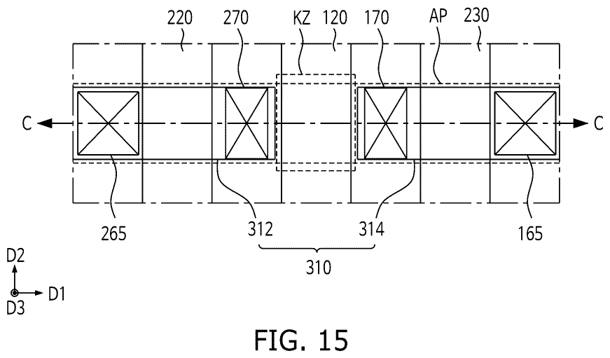

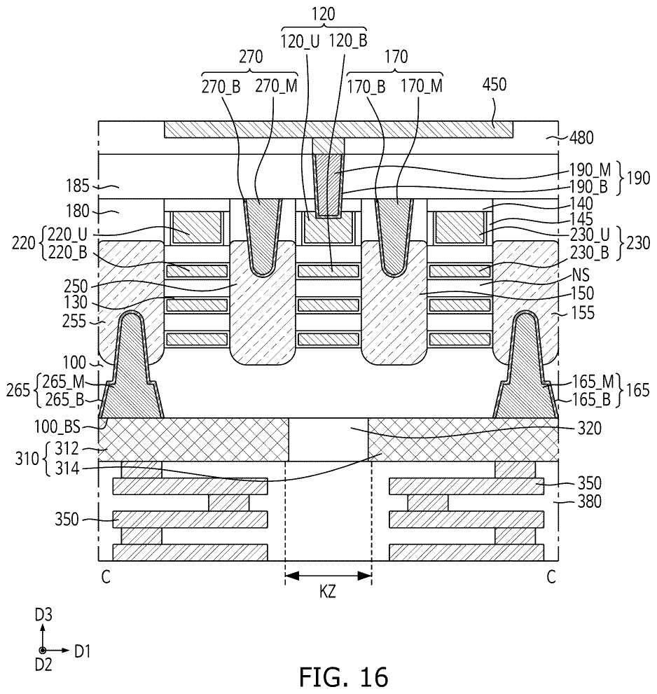

FIGS. 15 and 16 are diagrams of a semiconductor device according to some embodiments. For reference, FIG. 15 may be an example plan view provided to explain a semiconductor device according to some embodiments, and FIG. 16 may be a cross-sectional view taken along line C-C of FIG. 15. For convenience of description, features that are the same, substantially the same, or similar to those described previously may have their description omitted and different configurations from those described in FIGS. 1 to 4 will be primarily described.

Referring to FIGS. 15 and 16, the semiconductor device according to some embodiments may include the substrate 100, the plurality of sheet patterns NS, the first gate electrode 120, the second gate electrode 220, a third gate electrode 230, the gate insulating layer 130, the first source/drain pattern 150, the second source/drain pattern 250, a third source/drain pattern 155, a fourth source/drain pattern 255, a first lower source/drain contact 165, a second lower source/drain contact 265, the first interlayer insulating layer 180, the second interlayer insulating layer 185, the gate capping pattern 140, the gate spacer 145, a first upper source/drain contact 170, a second upper source/drain contact 270, the gate contact 190, the power wiring 310, the insulating layer 320, the lower wiring insulating layer 380, the lower wiring 350, and the upper wiring 450.

The first gate electrode 120 may be disposed between the first source/drain pattern 150 and the second source/drain pattern 250. The second gate electrode 220 may be disposed between the second source/drain pattern 250 and the fourth source/drain pattern 255. The third gate electrode 230 may be disposed between the first source/drain pattern 150 and the third source/drain pattern 155. Each of the first gate electrode 120, the second gate electrode 220, and the third gate electrode 230 may extend in the second direction D2.

The third gate electrode 230 may include a third upper gate electrode 230_U and a third lower gate electrode 230_B. Descriptions of the third upper gate electrode 230_U and the third lower gate electrode 230_B may be substantially the same as the descriptions of the first upper gate electrode 120_U and the first lower gate electrode 120_B.

In some embodiments, the power wiring 310 may include the first sub-power wiring 312 and the second sub-power wiring 314. Each of the first sub-power wiring 312 and the second sub-power wiring 314 may extend in the first direction D1. The first sub-power wiring 312 may be spaced apart from the second sub-power wiring 314 in the first direction D1. The first sub-power wiring 312 and the second sub-power wiring 314 may overlap in the first direction D1. For example, the width of the first sub-power wiring 312 in the second direction D2 and the width of the second sub-power wiring 314 in the second direction D2 may be the same as each other.

The insulating layer 320 may be disposed between the first sub-power wiring 312 and the second sub-power wiring 314. The first sub-power wiring 312 and the second sub-power wiring 314 may be spaced apart from each other in the first direction D1 by the insulating layer 320.

In some embodiments, the first gate electrode 120 may be disposed on the insulating layer 320. The first gate electrode 120 may not overlap with the power wiring 310 in the third direction D3. For example, the first gate electrode 120 may overlap with the insulating layer 320 disposed between the first sub-power wiring 312 and the second sub-power wiring 314 in the third direction D3. A portion of the first gate electrode 120 may be disposed on the keep-out region KZ. For example, from a planar perspective, a portion of the first gate electrode 120 may be disposed in the keep-out region KZ. A portion of the first gate electrode 120 may overlap with the keep-out region KZ in the third direction D3.

The first source/drain pattern 150, the second source/drain pattern 250, the third source/drain pattern 155, and the fourth source/drain pattern 255 may be disposed on the active region AP. Each of the first source/drain pattern 150, the second source/drain pattern 250, the third source/drain pattern 155, and the fourth source/drain pattern 255 may be disposed to be spaced apart from each other in the first direction D1.

The first upper source/drain contact 170 may be disposed on the first source/drain pattern 150. The first upper source/drain contact 170 may include a barrier film 170_B and a conductive filling film 170_M. The second upper source/drain contact 270 may be disposed on the second source/drain pattern 250. The second upper source/drain contact 270 may include the barrier film 270_B and the conductive filling film 270_M.

The first lower source/drain contact 165 may be disposed between the third source/drain pattern 155 and the power wiring 310. For example, the first lower source/drain contact 165 may be disposed on an upper surface of the second sub-power wiring 314 and may be formed to penetrate through the lower surface of the third source/drain pattern 155. The first lower source/drain contact 165 may include a barrier film 165_B and a conductive filling film 165_M.

The second lower source/drain contact 265 may be disposed between the fourth source/drain pattern 255 and the power wiring 310. For example, the second lower source/drain contact 265 may be disposed on an upper surface of the first sub-power wiring 312 and may be formed to penetrate through the lower surface of the fourth source/drain pattern 255. The second lower source/drain contact 265 may include a barrier film 265_B and a conductive filling film 265_M.

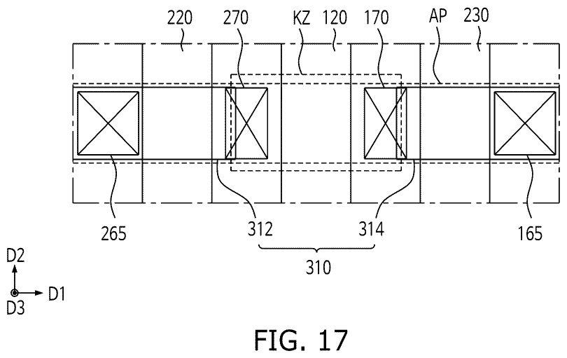

FIG. 17 is a diagram of a semiconductor device according to some embodiments. For convenience of explanation, features that are the same, substantially the same, or similar to those described previously may have their description omitted and different configurations from those described in FIGS. 15 and 16 will be primarily described.

Referring to FIG. 17, in the semiconductor device according to some embodiments, a portion of the second upper source/drain contact 270 may not overlap with the first sub-power wiring 312 in the third direction D3, and a portion of the first upper source/drain contact 170 may not overlap with the second sub-power wiring 314 in the third direction D3.

The insulating layer 320 may be disposed between the first sub-power wiring 312 and the second sub-power wiring 314. The insulating layer 320 may overlap with each of a portion of the first upper source/drain contact 170 and a portion of the second upper source/drain contact 270 in the third direction D3. For example, from a planar perspective, the first sub-power wiring 312 may expose a portion of the second upper source/drain contact 270, and the second sub-power wiring 314 may expose a portion of the first upper source/drain contact 170.

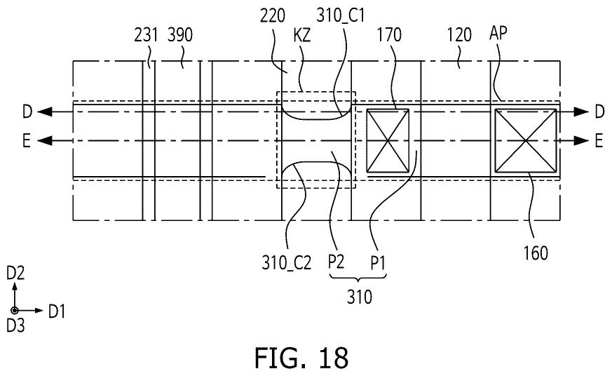

FIGS. 18 to 20 are diagrams of a semiconductor device according to some embodiments. For convenience of description, features that are the same, substantially the same, or similar to those described previously may have their description omitted and different configurations from those described in FIGS. 1 to 4 will be primarily described.

Referring to FIGS. 18 to 20, the semiconductor device according to some embodiments may include the substrate 100, the plurality of sheet patterns NS, the first gate electrode 120, the second gate electrode 220, the gate insulating layer 130, the first source/drain pattern 150, the second source/drain pattern 250, the fourth source/drain pattern 255, a fifth source/drain pattern 257, a lower source/drain contact 160, the first interlayer insulating layer 180, the second interlayer insulating layer 185, the gate capping pattern 140, the gate spacer 145, an isolation structure 390, the upper source/drain contact 170, a first gate contact 190, a second gate contact 290, the power wiring 310, the insulating layer 320, the lower wiring insulating layer 380, the lower wiring 350, and the upper wiring 450.

The first gate electrode 120 may be disposed between the first source/drain pattern 150 and the second source/drain pattern 250. The second gate electrode 220 may be disposed between the second source/drain pattern 250 and the fourth source/drain pattern 255. Each of the first gate electrode 120 and the second gate electrode 220 may extend in the second direction D2.

The first gate contact 190 may be disposed on the first gate electrode 120. The first gate contact 190 may be formed through the second interlayer insulating layer 185 and the upper surface of the first upper gate electrode 120_U. The first gate contact 190 may be electrically connected to the first gate electrode 120. The first gate contact 190 may include the barrier film 190_B and the conductive filling film 190_M.

The second gate contact 290 may be disposed on the second gate electrode 220. The second gate contact 290 may be formed through the second interlayer insulating layer 185 and an upper surface of the second upper gate electrode 220_U. The second gate contact 290 may be electrically connected to the second gate electrode 220. The second gate contact 290 may include a barrier film 290_B and a conductive filling film 290_M.

In some embodiments, the upper wiring 450 may be disposed on the first gate contact 190 and the second gate contact 290. The upper wiring 450 may be connected to each of the first gate contact 190 and the second gate contact 290. The second gate electrode 220 may be connected to the first gate electrode 120 through the second gate contact 290, the upper wiring 450, and the first gate contact 190.

The power wiring 310 may be disposed on the lower surface 100_BS of the substrate 100. The power wiring 310 may extend in the first direction D1. The power wiring 310 may include the first portion P1 having the first width W1 in the second direction D2 and the second portion P2 having the second width W2 in the second direction D2. The second width W2 may be less than the first width W1. The power wiring 310 may include the first side surface 310_C1 and the second side surface 310_C2. The insulating layer 320 may be disposed on the first side surface 310_C1 and the second side surface 310_C2 of the power wiring 310.

The second portion P2 of the power wiring 310 may overlap with a portion of the second gate electrode 220 in the third direction D3. For example, the remaining portion of the second gate electrode 220 may not overlap with the second portion P2 of the power wiring 310 in the third direction D3. Each of the insulating layer 320 disposed on the first side surface 310_C1 of the power wiring 310 and the insulating layer 320 disposed on the second side surface 310_C2 of the power wiring 310 may overlap with the second gate electrode 220 in the third direction D3.

The keep-out region KZ may overlap with the second portion P2 of the power wiring 310 in the third direction D3. The keep-out region KZ may overlap with each of the insulating layer 320 disposed on the first side surface 310_C1 of the power wiring 310 and the insulating layer 320 disposed on the second side surface 310_C2 of the power wiring 310 in the third direction D3.

In some embodiments, the electrical characteristics of the transistor that includes the first gate electrode 120 may be inspected. For example, the electrical characteristics of the second gate electrode 220, which does not overlap with the power wiring 310 in the third direction D3 through the keep-out region KZ and the insulating layer 320, may be inspected. Since the second gate electrode 220 is electrically connected to the first gate electrode 120, the electrical characteristics of the transistor that includes the first gate electrode 120 may be inspected through the second gate electrode 220.

The isolation structure 390 may be disposed to be spaced apart from the second gate electrode 220 in the first direction D1. The isolation structure 390 may be disposed between the fourth source/drain pattern 255 and the fifth source/drain pattern 257. The isolation structure 390 may extend in the second direction D2. The isolation structure 390 may separate the fourth source/drain pattern 255 from the fifth source/drain pattern 257. In some embodiments, a residual gate electrode 231 may be disposed on a sidewall of the isolation structure 390.

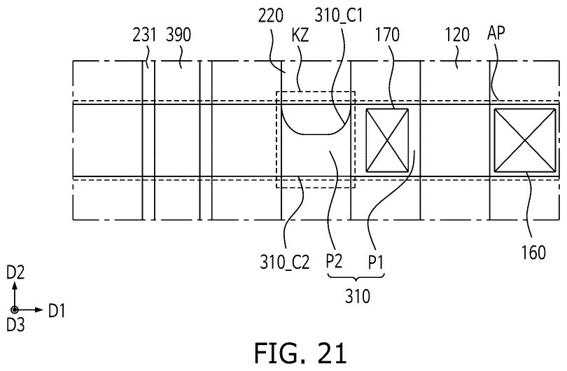

FIG. 21 is a diagram of a semiconductor device according to some embodiments. For convenience of description, features that are the same, substantially the same, or similar to those described previously may have their description omitted and different configurations from those described in FIGS. 18 to 20 will be primarily described.

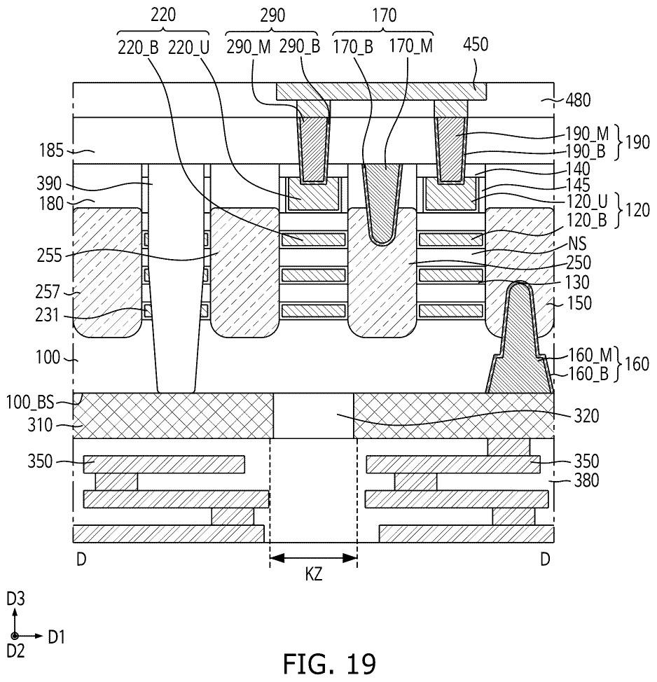

Referring to FIG. 21, in the semiconductor device according to some embodiments, the power wiring 310 may include the first portion P1 and the second portion P2. The width of the second portion P2 in the second direction D2 may be less than the width of the first portion P1 in the second direction D2. The power wiring 310 may include the first side surface 310_C1 and the second side surface 310_C2 that is opposite to the first side surface 310_C1 in the second direction D2. The first side surface 310_C1 may be recessed, and the second side surface 310_C2 may extend parallel to the first direction D1. The insulating layer 320 (see FIG. 19) may be disposed on the first side surface 310_C1 of the power wiring 310. The insulating layer 320 disposed on the first side surface 310_C1 of the power wiring 310 may overlap with the second gate electrode 220 in the third direction D3.

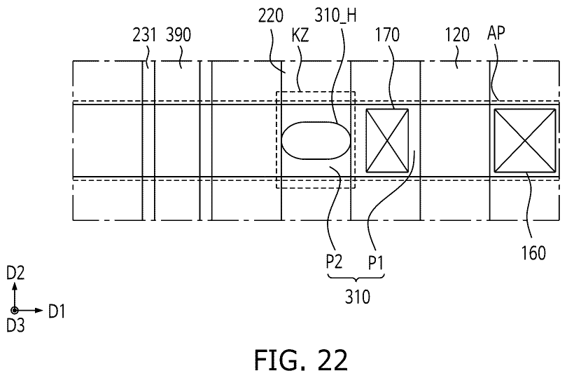

FIG. 22 is a diagram of a semiconductor device according to some embodiments. For convenience of description, features that are the same, substantially the same, or similar to those described previously may have their description omitted and different configurations from those described in FIGS. 18 to 20 will be primarily described.

Referring to FIG. 22, the semiconductor device according to some embodiments may include the through hole 310_H disposed within the power wiring 310. The through hole 310_H may be disposed on the active region AP. The through hole 310_H may overlap with the active region AP in the third direction D3. For example, the through hole 310_H may overlap with the second gate electrode 220 in the third direction D3.

In some embodiments, the insulating layer 320 (see in FIG. 19) may be disposed within the through hole 310_H. The insulating layer 320 may fill the through hole 310_H. However, embodiments are not limited to the above. For example, the interior of the through hole 310_H may be an empty space (e.g., filled with a gas). The through hole 310_H may be referred to as a cavity or an air gap. The insulating layer 320 may overlap with the second gate electrode 220 in the third direction D3. From a planar perspective, the insulating layer 320 may be disposed in the keep-out region KZ.

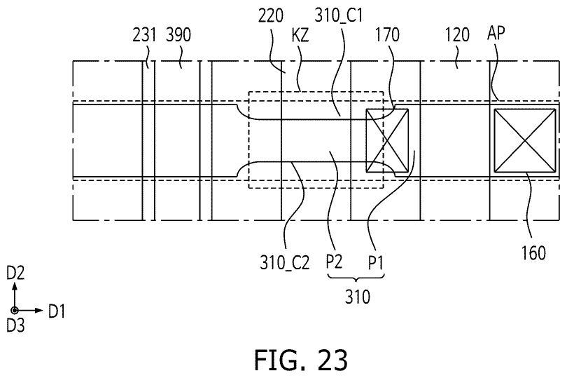

FIG. 23 is a diagram of a semiconductor device according to some embodiments. For convenience of description, different configurations from those described in FIGS. 18 to 20 will be primarily described.

Referring to FIG. 23, in the semiconductor device according to some embodiments, a length of the second portion P2 of the power wiring 310 in the first direction D1 may be greater than a width of the second gate electrode 220 in the first direction D1.

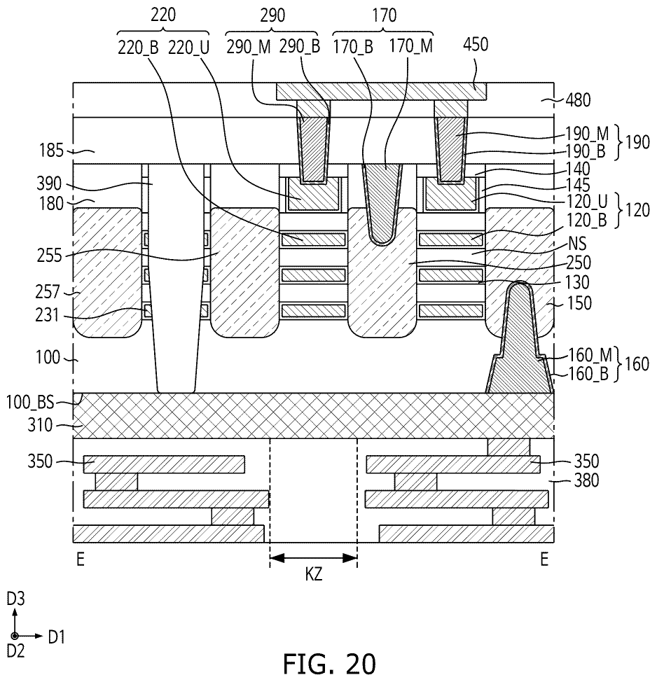

Unlike the illustrations in FIGS. 18 to 20, the second portion P2 of the power wiring 310 may protrude from the second gate electrode 220. For example, from a planar perspective, the second portion P2 of the power wiring 310 may protrude farther than the second gate electrode 220 in the first direction D1. The second portion P2 of the power wiring 310 may overlap with the fourth source/drain pattern 255 of FIG. 20 in the third direction D3. The second portion P2 of the power wiring 310 may overlap with the second source/drain pattern 250 of FIG. 20 in the third direction D3. In addition, the second portion P2 of the power wiring 310 may overlap with the upper source/drain contact 170 in the third direction D3.

It may be difficult to form the second portion P2 of the power wiring 310 within a predetermined distance interval. For example, forming the second portion P2 of the power wiring 310 between the gate electrode and adjacent gate electrode may be a difficult process. On the other hand, according to some embodiments, the second portion P2 of the power wiring 310 may be formed to extend to the second source/drain pattern (250 of FIG. 20) and the fourth source/drain pattern (255 of FIG. 20) adjacent to the second gate electrode 220 such that the second portion P2 of the power wiring 310 may be easily formed. Accordingly, the reliability of the semiconductor device may be further improved.

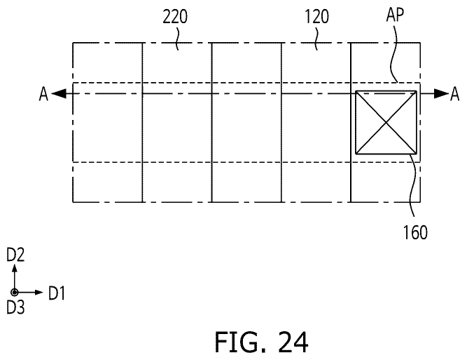

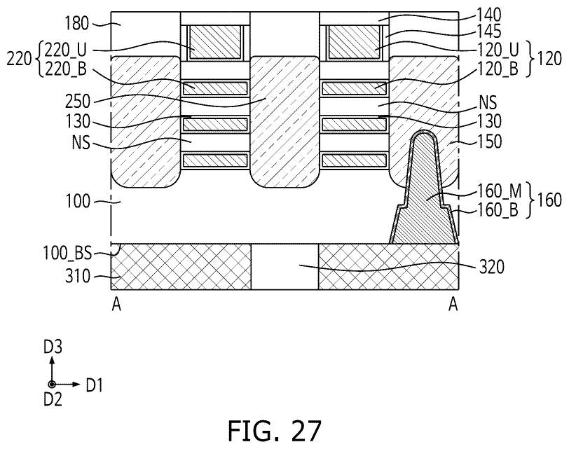

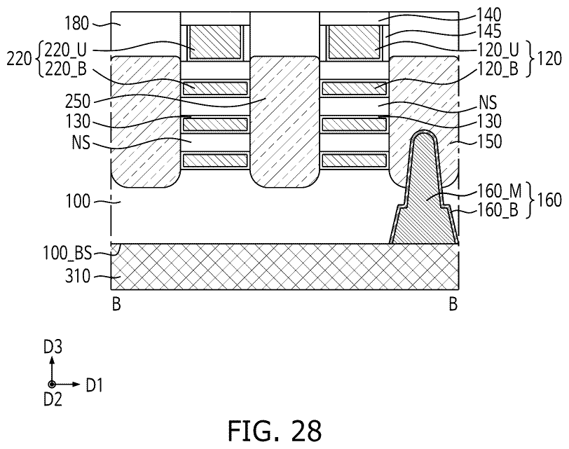

FIGS. 24 to 30 are diagrams illustrating intermediate stages during a method for manufacturing a semiconductor device according to some embodiments. For convenience of description, features that are the same, substantially the same, or similar to those described previously in the description of the embodiments of FIGS. 1 to 23 may be omitted or briefly described.

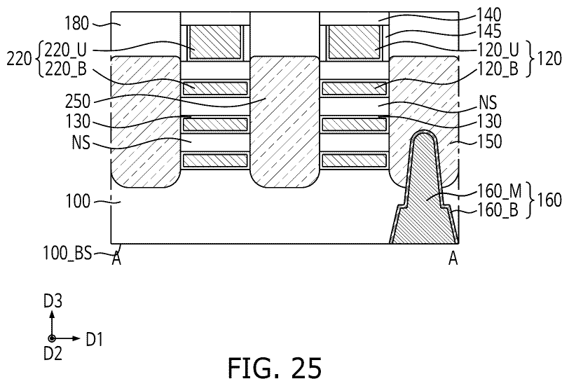

Referring to FIGS. 24 and 25, in a method for manufacturing the semiconductor device according to some embodiments, the plurality of sheet patterns NS, the source/drain patterns 150 and 250, the gate electrodes 120 and 220, the gate spacer 145, the gate capping pattern 140, the first interlayer insulating layer 180, and the lower source/drain contact 160 may be provided on the substrate 100.

For example, the plurality of sheet patterns NS, the source/drain patterns 150 and 250, the gate electrodes 120 and 220, the gate spacer 145, the gate capping pattern 140, and the first interlayer insulating layer 180 may be formed on the semiconductor substrate. The semiconductor substrate may be removed, and the substrate 100 may be formed. The substrate 100 may include an insulating material. A portion of the substrate 100 may be removed to form a trench. The trench may expose a portion of the first source/drain pattern 150. The barrier film 160_B and the conductive filling film 160_M of the lower source/drain contact 160 may be formed within the trench.

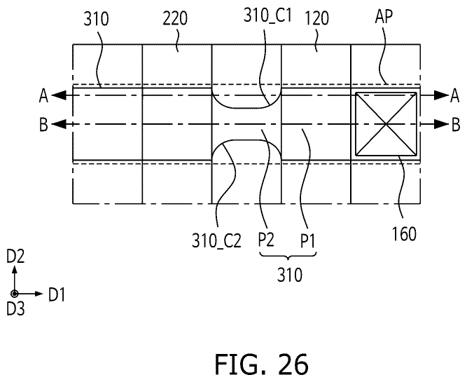

Referring to FIGS. 26 to 29, the power wiring 310 and the insulating layer 320 may be formed on the lower surface 100_BS of the substrate 100.

The power wiring 310 may extend in the first direction D1. The power wiring 310 may include the first portion P1 having a first width in the second direction D2 and the second portion P2 having a second width in the second direction D2. The first width may be greater than the second width. The second portion P2 of the power wiring 310 may overlap with the second source/drain pattern 250 in the third direction D3.

In some embodiments, the second portion P2 of the power wiring 310 may include the first side surface 310_C1 and the second side surface 310_C2. The first side surface 310_C1 and the second side surface 310_C2 may have a recessed shape. The first side surface 310_C1 and the second side surface 310_C2 may be opposite to each other in the second direction D2. The insulating layer 320 may be disposed on the second portion P2 of the power wiring 310.

Although it is illustrated that the first side surface 310_C1 and the second side surface 310_C2 of the power wiring 310 have a recessed shape, this should be understood as only an example. In some embodiments, the power wiring 310 may include the first side surface 310_C1, which is recessed, and the second side surface 310_C2, which is flat, as illustrated in FIG. 5. In some embodiments, the power wiring 310 may include the through hole 310_H as illustrated in FIG. 6.

Although it is illustrated that the second portion P2 of the power wiring 310 overlaps with the second source/drain pattern 250 in the third direction D3, this should be understood as only an example. In some embodiments, the second portion P2 of the power wiring 310 may overlap with the first gate electrode 120 in the third direction D3 as illustrated in FIG. 16, and may overlap with the second gate electrode 220 in the third direction D3 as illustrated in FIGS. 18 to 23.

In some embodiments, the power wiring 310 may include the first sub-power wiring 312 and the second sub-power wiring 314 as illustrated in FIGS. 12 and 15 to 17. Hereinafter, it will be described that the power wiring 310 includes the first side surface 310_C1 and the second side surface 310_C2, and that the first side surface 310_C1 and the second side surface 310_C2 have a recessed shape.

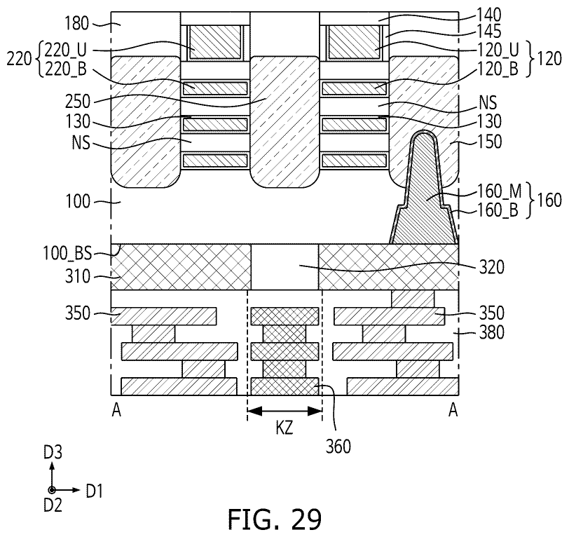

Referring to FIG. 29, the lower wiring 350 and the dummy wiring 360 may be formed below the power wiring 310.

The lower wiring 350 and the dummy wiring 360 may be disposed within the lower wiring insulating layer 380. The lower wiring insulating layer 380 may include the keep-out region KZ. The dummy wiring 360 may be disposed in the keep-out region KZ. The lower wiring 350 may not be disposed on the keep-out region KZ. The lower wiring 350 may be connected to the power wiring 310. The dummy wiring 360 may not be connected to the power wiring 310.

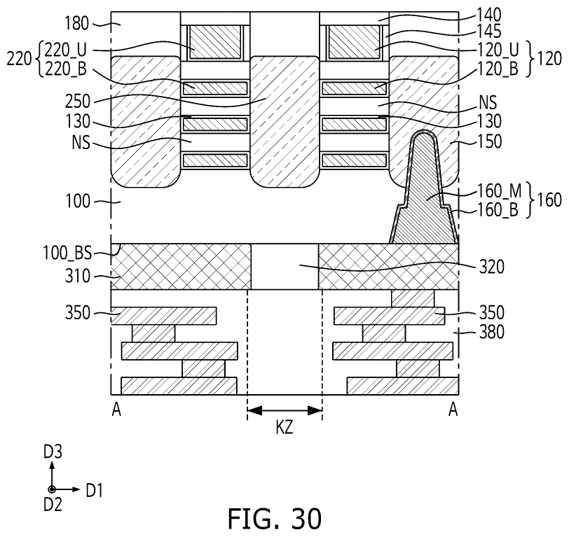

Referring to FIG. 30, the dummy wiring 360 (see in FIG. 29) may be removed. The lower wiring insulating layer 380 may fill the space left after removing the dummy wiring 360. Referring to FIGS. 3 and 4, the second interlayer insulating layer 185, the gate contact 190, the upper wiring insulating layer 480, and the upper wiring 450 may be formed. In some embodiments, the dummy wiring 360 may not be removed. For example, as shown in FIG. 7, the dummy wiring 360 may be disposed within the lower wiring insulating layer 380.

Although certain embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A semiconductor device, comprising:
a substrate comprising an active region extending in a first direction;
a sheet pattern disposed on the active region;
a first gate electrode surrounding the sheet pattern and extending in a second direction that intersects with the first direction;
a first source/drain pattern on the active region, wherein the first source/drain pattern is disposed on a first side of the sheet pattern;
a second source/drain pattern on the active region, wherein the second source/drain pattern is disposed on a second side of the sheet pattern opposite the first side;
a power wiring on a lower surface of the substrate, wherein the power wiring extends in the first direction, and comprises a first portion having a first width in the second direction and a second portion having a second width in the second direction that is less that the first width; and
a lower wiring disposed below the power wiring, wherein
the lower wiring does not overlap with the second portion of the power wiring in a third direction that is perpendicular to the lower surface of the substrate.

2. The semiconductor device according to claim 1, wherein
the second portion of the power wiring comprises a first side surface, and
the first side surface has a recessed shape.

3. The semiconductor device according to claim 2, wherein
the second portion of the power wiring further comprises a second side surface that is opposite to the first side surface in the second direction, and
the second side surface has a recessed shape.

4. The semiconductor device according to claim 1, further comprising an upper source/drain contact disposed on the second source/drain pattern, wherein
a portion of the second source/drain pattern does not overlap with the second portion of the power wiring in the third direction.

5. The semiconductor device according to claim 1, further comprising:
an insulating layer overlapping with the power wiring in the first direction; and
a dummy wiring disposed adjacent to the lower wiring, wherein
the dummy wiring overlaps with the insulating layer in the third direction.

6. The semiconductor device according to claim 1, wherein the active region overlaps with the power wiring in the third direction.

7. The semiconductor device according to claim 1, further comprising a first lower source/drain contact disposed on an upper surface of the power wiring and penetrating through a lower surface of the first source/drain pattern.

8. The semiconductor device according to claim 7, wherein a side surface of the first lower source/drain contact has a step.

9. The semiconductor device according to claim 1, further comprising a second lower source/drain contact disposed on the second portion of the power wiring and penetrating through a lower surface of the second source/drain pattern, wherein
a portion of the second lower source/drain contact does not overlap with the second portion of the power wiring in the third direction.

10. The semiconductor device according to claim 1, further comprising a second gate electrode spaced apart from the first gate electrode in the first direction and extending in the second direction, wherein
the second gate electrode is disposed on a side surface of the second source/drain pattern, and
the second portion of the power wiring overlaps with the second gate electrode in the third direction.

11. The semiconductor device according to claim 10, further comprising:
a first gate contact disposed on the first gate electrode;
a second gate contact disposed on the second gate electrode; and
an upper wiring connecting the first gate contact to the second gate contact.

12. A semiconductor device, comprising:
a substrate comprising an active region extending in a first direction;
a sheet pattern disposed on the active region;
a first gate electrode surrounding the sheet pattern and extending in a second direction that intersects with the first direction;
a first source/drain pattern on the active region, wherein the first source/drain pattern is disposed on a first side of the sheet pattern;
a second source/drain pattern on the active region, wherein the second source/drain pattern is disposed on a second side of the sheet pattern;
a power wiring disposed on a lower surface of the substrate, extending in the first direction, and overlapping with the active region in a third direction that is perpendicular to the lower surface of the substrate;
a lower wiring insulating layer disposed on a lower surface of the power wiring; and
an insulating layer disposed between the lower surface of the substrate and the lower wiring insulating layer and overlapping with at least a portion of the power wiring in the first direction.

13. The semiconductor device according to claim 12, wherein
the power wiring comprises a first portion having a first width in the second direction and a second portion having a second width in the second direction that is less the first width, and
the insulating layer is disposed on a side surface of the second portion of the power wiring.

14. The semiconductor device according to claim 13, further comprising a lower wiring disposed in the lower wiring insulating layer, wherein
the lower wiring insulating layer comprises a keep-out region where the lower wiring is not disposed, and
the keep-out region overlaps with the second portion of the power wiring in the third direction.

15. The semiconductor device according to claim 12, further comprising a lower wiring disposed in the lower wiring insulating layer, wherein
the active region comprises a first region overlapping with the power wiring in the third direction and a second region overlapping with the insulating layer in the third direction, and
the lower wiring does not overlap with the second region in the third direction.

16. The semiconductor device according to claim 12, further comprising a second gate electrode spaced apart from the first gate electrode in the first direction and extending in the second direction, wherein
the second gate electrode is disposed on a side surface of the second source/drain pattern, and
the insulating layer overlaps with the second gate electrode in the third direction.

17. The semiconductor device according to claim 12, further comprising a through hole disposed in the power wiring, wherein
the insulating layer is disposed in the through hole.

18. The semiconductor device according to claim 17, further comprising an upper source/drain contact disposed on the second source/drain pattern, wherein
a portion of the upper source/drain contact overlaps with a portion of the through hole in the third direction.

19. The semiconductor device according to claim 12, wherein
the power wiring comprises a first sub-power wiring extending in the first direction and a second sub-power wiring spaced apart from the first sub-power wiring in the first direction,
the insulating layer is disposed between the first sub-power wiring and the second sub-power wiring, and
the insulating layer overlaps with the first gate electrode in the third direction.

20. A semiconductor device, comprising:
a substrate comprising an active region extending in a first direction;
a sheet pattern disposed on the active region;
a first gate electrode surrounding the sheet pattern and extending in a second direction that intersects with the first direction;
a first source/drain pattern on the active region, wherein the first source/drain pattern is disposed on a first side of the sheet pattern;
a second source/drain pattern on the active region, wherein the second source/drain pattern is disposed on a second side of the sheet pattern;
a power wiring on a lower surface of the substrate, wherein the power wiring extends in the first direction, and comprises a first portion having a first width in the second direction and a second portion having a second width in the second direction that is less than the first width;
an upper source/drain contact disposed on the second source/drain pattern;
a lower source/drain contact disposed on an upper surface of the power wiring and penetrating through a lower surface of the first source/drain pattern; and
a lower wiring disposed below the power wiring, wherein
the lower wiring does not overlap with the second portion of the power wiring in a third direction that is perpendicular to the lower surface of the substrate,
the active region overlaps with the power wiring in the third direction, and
the second portion overlaps with the upper source/drain contact in the third direction.
